(19) United States
(12) Patent Application Publication
(10) Pub. No.: US 2023/0288542 A1
(43) Pub. Date: Sep. 14, 2023

(54) LASER EMISSION CONTROL METHOD, DRIVE CIRCUIT, AND LIDAR

(71) Applicant: Hesai Technology Co., Ltd., (US)

(72) Inventors: Yuntian BI, Shanghai (CN); Jianfeng LIU, Shanghai (CN); Xin ZHAO, Shanghai (CN); Shaoqing XIANG, Shanghai (CN)

(21) Appl. No.: 18/199,440

(22) Filed: May 19, 2023

Related U.S. Application Data
(63) Continuation of application No. PCT/CN2021/106649, filed on Jul. 16, 2021.

(30) Foreign Application Priority Data
Dec. 4, 2020 (CN) CN202011407125.8

(51) Int. Cl. G01S 7/484; G01R 19/165; G01S 7/481

(52) U.S. Cl. CPC G01S 7/484; G01R 19/16576; G01S 7/4814

(57) ABSTRACT

Methods, drive circuits, and lidars for laser emission control are provided. The drive circuit is configured to be coupled to a laser device and an energy storage unit, and includes a drive unit, a switch unit, and a detection unit. The energy storage unit includes a first terminal coupled to the laser device and the switch unit. The energy storage unit also includes a second terminal grounded, and forms the voltage supply path with a supplied voltage and the switch unit to perform charging based on a switch signal of a second control terminal, and to perform discharging based on a laser emission trigger signal of a first control terminal. The detection unit is configured to detect a signal of the first terminal of the energy storage unit during discharging and generate a corresponding state feedback signal based on a comparison of the signal with a preset threshold.

### CROSS-REFERENCE

This application is a Continuation application of International PCT Application No. PCT/CN2021/106649, filed on Jul. 16, 2021, which claims the benefit of Chinese Application No. CN202011407125.8, filed on Dec. 4, 2020, the content of each of which is incorporated herein by reference in its entirety.

### TECHNICAL FIELD

Embodiments of the description relate to the technical field of electronic circuits, and in particular, to methods, drive circuits, and lidars for laser emission control.

### BACKGROUND

A lidar (Light Detection and Ranging) is a sensor that provides precise ranging by using a laser. The lidar emits laser pulses, which are reflected back when the pulses encounter surrounding objects. A precise distance to each object may be calculated by measuring a time it takes the laser to reach and return from the object. The lidar emits thousands of pulses per second. By collecting distance measurements, a three-dimensional environment model, referred to as a point cloud, may be built.

The lidar has a wide range of applications, including: autonomous driving (specifically, the lidar may be applied to autonomous taxis, buses, trucks, logistics vehicles, or the like), mapping, smart cities/V2X, robotics, security, and the like. V2X, that is, Vehicle to Everything, represents a way of communication between a vehicle and others in the outside world. “X” may represent any object that can communicate with the vehicle. The communication may be, for example, vehicle-to-vehicle communication, vehicle-to-human communication, vehicle-to-road infrastructure communication, vehicle-to-cloud network communication, or the like.

Based on the optical characteristics of lasers and the core status of the lidar in sensors in the field, a lidar emission terminal needs to emit laser signals normally and stably.

### SUMMARY

Based on the above, according to an aspect of embodiments of the description, a laser emission drive circuit is provided, which is configured to monitor an operating state of the laser emission circuit.

According to another aspect of embodiments of the description, a method for laser emission control and a lidar are provided, which can ensure a normal operation of the laser device based on an operating state of the laser device obtained by monitoring.

First, embodiments of the description provide a laser emission drive circuit. The laser emission drive circuit is adapted to be coupled to a laser device and an energy storage unit includes: a drive unit, a switch unit, and a detection unit, where the drive unit is adapted to strobe a light-emitting circuit of the laser device based on a laser emission trigger signal of a first control terminal, to cause the laser device to emit light; the switch unit is adapted to strobe a voltage supply path in response to a switch signal of a second control terminal, and charge the energy storage unit; a first terminal of the energy storage unit is coupled to the laser device and the switch unit, and a second terminal of the energy storage unit is grounded, the energy storage unit forms the voltage supply path with a supplied voltage and the switch unit to perform charging based on the switch signal of the second control terminal, and to perform discharging based on the laser emission trigger signal of the first control terminal, and forms the light-emitting circuit of the laser with the drive unit and the ground; and the detection unit is coupled to the switch unit, the laser device, and the energy storage unit, and is adapted to detect a signal of the first terminal of the energy storage unit during discharging, compare the signal with a preset threshold, and generate a corresponding state feedback signal based on a comparison result.

Optionally, the detection unit includes at least one detection module; and the detection module includes a first input terminal, a second input terminal, and a state feedback signal output terminal, where the first input terminal is adapted to be coupled to the first terminal of the energy storage unit, the second input terminal is adapted for the input of a threshold corresponding to the detection module, and the state feedback signal output terminal is adapted for the output of the corresponding state feedback signal based on a magnitude relationship between an output signal of the energy storage unit detected at the first input terminal and the threshold inputted at the second input terminal.

Optionally, the detection unit includes: a first detection module, configured to compare a voltage signal detected at the first input terminal with a first threshold voltage inputted at the second input terminal, and output a first state feedback signal when a minimum voltage detected at the first input terminal is less than the first threshold voltage, where the first threshold voltage is related to a human eye safety protection threshold.

Optionally, the detection unit further includes: a second detection module, configured to compare the voltage signal detected at the first input terminal with a second threshold voltage inputted at the second input terminal, and output a second state feedback signal when the minimum voltage detected at the first input terminal is less than the second threshold voltage, where the second threshold voltage is related to a minimum energy required for normal operation of the laser device, and the second threshold voltage is greater than the first threshold voltage.

Optionally, the detection unit further includes: a third detection module, configured to compare a voltage signal detected at the first input terminal with a third threshold voltage inputted at the second input terminal, and output a third state feedback signal when the minimum voltage detected at the first input terminal is less than the third threshold voltage, where the third threshold voltage is between the first threshold voltage and the second threshold voltage, and is related to a current preset luminous intensity of the laser device.

Optionally, the detection unit further includes: a voltage dividing module, coupled between the first terminal of the energy storage unit and the ground and coupled to the first input terminal of the at least one detection module through a voltage dividing terminal; and a voltage regulating module, adapted to initialize the voltage at the voltage dividing terminal.

Optionally, the voltage dividing module includes: a first capacitor and a second capacitor coupled between the first terminal of the energy storage unit and the ground, and the voltage dividing terminal is arranged between the first capacitor and the second capacitor.

Optionally, the energy storage unit includes: a third capacitor, and a ratio of a capacitance value of the third capacitor to a capacitance value of either the first capacitor or the second capacitor is greater than 1000.

Optionally, the voltage dividing module includes: a first resistor and a second resistor coupled between the first terminal of the energy storage unit and the ground, and the voltage dividing terminal is arranged between the first resistor and the second resistor.

An embodiment of the description further provides a lidar, including: a laser device, adapted to emit a laser in response to a laser emission trigger signal; the laser emission drive circuit mentioned in the foregoing embodiment; a control unit, adapted to: output a switch signal to control a switch unit in the laser emission drive circuit to strobe a voltage supply path to charge the energy storage unit; output the laser emission trigger signal to control the drive unit to strobe a light-emitting circuit of the laser device, to cause the laser device to emit light; and receive a state feedback signal generated by the laser emission drive circuit, and perform corresponding processing based on the state feedback signal; and an energy storage unit, adapted to be coupled to the laser emission drive circuit and the laser device, to perform discharging based on the laser emission trigger signal outputted by the control unit, and to perform charging based on the switch signal outputted by the control unit.

The control unit is adapted to perform the corresponding processing based on whether the state feedback signal is received and a type of the state feedback signal received.

Optionally, the state feedback signal includes a first state feedback signal, and the control unit is adapted to generate a laser device turn-off signal in response to the first state feedback signal, to control the laser device to stop operating.

Optionally, the state feedback signal includes a first state feedback signal, and the control unit is adapted to control the first terminal of the energy storage unit to be grounded, set an emission channel corresponding to the laser device as a light-emission-prohibited channel, and output human eye safety alarm information in response to the first state feedback signal.

Optionally, the state feedback signal includes a first state feedback signal and a second state feedback signal, and the control unit is adapted to perform accumulative counting when the control unit does not receive the first state feedback signal and the second state feedback signal within a preset duration since the laser emission trigger signal is outputted, and output a blind line alarm signal when a counted value reaches a preset counting threshold.

Optionally, the state feedback signal includes a third state feedback signal, and the control unit is adapted to output a corresponding excessive light intensity alarm signal when receiving the third state feedback signal.

An embodiment of the description further provides a method for laser emission control. The method is applicable to the lidar described in the foregoing embodiment, including: based on a preset emission control parameter, outputting a switch signal to the laser emission drive circuit, and outputting a laser emission trigger signal to the laser device to control the laser device to emit light; and performing corresponding processing based on the state feedback signal outputted by the laser emission drive circuit.

The method and apparatus of the present disclosure provide benefits and improvements over conventional lidar devices. According to an aspect, the laser emission drive circuit in the embodiment of the description is used. The output signal at the first terminal of the energy storage unit is detected by the detection unit, and compared with the preset threshold value, the corresponding state feedback signal is generated based on the comparison result, which can realize the monitoring of the operating state of the laser device and discover an anomaly in time. Moreover, a continuous supply of voltage to the laser device can be prevented by controlling the on-off between the supplied voltage and the laser device through the switch unit, thereby preventing a case that the related circuits of the laser device are instantly broken down and damaged when being short-circuited.

According to another aspect, the method for laser emission control and the lidar in the embodiment of the description are used. The operating state of the laser device is monitored through the laser emission drive circuit, and a corresponding processing is performed based on the state feedback signal generated by the laser emission drive circuit, so that a fault of the laser device can be identified in time. Further, the laser device can be guaranteed to operate normally through the corresponding processing.

Further, the first detection module outputs the first state feedback signal when a minimum voltage detected at the first input terminal coupled with the first terminal of the energy storage unit is less than the first threshold voltage inputted at the second input terminal, and the first threshold voltage is related to a human eye safety protection threshold. The first state feedback signal can trigger a generation of a human eye safety protection signal, and then a corresponding human eye safety protection measure can be adopted. For example, the laser device can be controlled to stop operating, or the first terminal of the energy storage unit can be controlled to be grounded, the corresponding emission channel of the laser device can be set as a prohibited light-emitting channel, and human eye safety alarm information can be outputted. Therefore, the laser device can be avoided to continue to emit the laser, ensure the safety of human eyes, and improve use safety of the radar.

Further, the second detection module outputs the second state feedback signal when a minimum voltage detected at the first input terminal coupled with the first terminal of the energy storage unit is less than the second threshold voltage inputted at the second input terminal. The second threshold voltage is related to a minimum value of energy required by the laser device for a normal operation, and the second threshold voltage is greater than the first threshold voltage. Therefore, when the second state feedback signal is monitored but the first state feedback signal is not monitored, it means that the laser device is in a normal operating state. However, if the control unit does not receive the first state feedback signal or the second state feedback signal within a preset duration after the output of the laser emission trigger signal, it represents that the laser device operates abnormally and can be processed according to a preset processing strategy. For example, a cumulative counting can be performed and a blind line alarm signal can be outputted when a counted value reaches the preset counting threshold, so that a user can timely troubleshoot the fault based on the blind line alarm signal, to avoid a lack of detection results caused by the inability of the corresponding emission channel of the laser device to emit laser, and to ensure the detection performance.

Further, the third detection module outputs the third state feedback signal when a minimum voltage detected at the first input terminal coupled with the first terminal of the energy storage unit is less than the third threshold voltage inputted at the second input terminal. Since the third threshold voltage is between the first threshold voltage and the second threshold voltage and is related to a preset luminous intensity of the laser device for that time, the control unit can output a corresponding excessive light intensity alarm signal based on the received third state feedback signal, so that the user can perceive the operating state of the laser device of the lidar in a more refined way, and then can realize more accurate control of the operating state of the laser device.

Further, the voltage at the voltage dividing terminal changes synchronously and proportionally with the voltage change at the first terminal of the energy storage unit through the voltage dividing module coupled between the first terminal of the energy storage unit and the ground, and the voltage dividing terminal of the voltage dividing module is coupled to the first input terminal of the at least one detection module. Therefore, the voltage at the first terminal of the energy storage unit can be prevented from directly entering the first input terminal of the detection module. As a result, the detection module can be realized by using a low-voltage device.

Further, the voltage division is performed through the first capacitor and the second capacitor coupled between the first terminal of the energy storage unit and the ground. Since the direct current signal cannot pass through the capacitor, the direct current loss can be reduced and the influence of voltage monitoring on the laser device can be reduced.

### BRIEF DESCRIPTION OF THE ACCOMPANYING DRAWINGS

In order to describe the technical solutions in embodiments of this application or the related art more clearly, the following briefly describes the accompanying drawings required for describing the embodiments or the related art. Apparently, the accompanying drawings in the following description show only the embodiments of this application, and those of ordinary skill in the art may still derive other accompanying drawings from the accompanying drawings without creative efforts.

FIG. 1 is a schematic structural diagram representing an example laser emission drive circuit according to an embodiment of the description.

FIG. 2 is a schematic structural diagram representing an example detection unit according to an embodiment of the description.

FIG. 3 is a schematic structural diagram representing another example detection unit according to an embodiment of the description.

FIG. 4 is a schematic structural diagram representing an example laser emission circuit in a specific application scenario according to an embodiment of the description.

FIG. 5 is a schematic structural diagram representing an example laser emission circuit in another specific application scenario according to an embodiment of the description.

FIG. 6 is a schematic structural diagram representing an example laser emission system according to an embodiment of the description.

FIG. 7 is a schematic structural diagram representing an example lidar according to an embodiment of the description.

FIG. 8 is a flowchart of an example method for laser emission control according to an embodiment of the description.

FIG. 9 to FIG. 11 are input-output waveform diagrams representing an example laser emission drive circuit according to some embodiments of the description.

FIG. 12 is a schematic diagram representing an example of detected voltage waveform of a first terminal of an energy storage unit according to an embodiment of the description.

### DETAILED DESCRIPTION

As described in the background, a lidar is a core sensor device in a plurality of fields such as autonomous driving, mapping, smart cities/V2X, robotics, and security. Therefore, normal and stable operation of a lidar and a lidar emission terminal included in the lidar is a necessary for normal operation of devices in the plurality of fields equipped with the lidar. However, there is no corresponding detection guarantee mechanism for the laser emission of the laser emission terminal.

Based on the above, embodiments of the description provide a corresponding detection and laser emission control solution. On one hand, a laser emission drive circuit is used to monitor operating states of a laser device and the drive circuit, and a corresponding state feedback signal is outputted. On the other hand, corresponding processing is performed based on the state feedback signal outputted by the laser emission drive circuit, to realize signal detection and corresponding normal operation guarantee of the lidar emission terminal.

In order to enable a person skilled in the art to better understand the concepts, advantages, and implementations of the solutions provided in the description, principles of the solutions such as the laser emission drive circuit, the method for laser emission control, and the lidar provided in the embodiments of the description are described in detail and exemplified through specific embodiments with reference to the drawings.

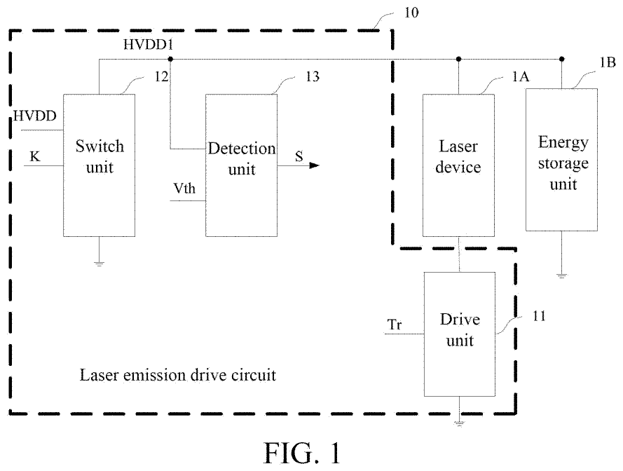

In some embodiments of the description, FIG. 1 is a schematic structural diagram representing an example laser emission drive circuit. A laser emission drive circuit 10 is adapted to be coupled to a laser device 1A and an energy storage unit 1B. Specifically, the laser emission drive circuit 10 may include a drive unit 11, a switch unit 12, and a detection unit 13.

The drive unit 11 is adapted to strobe a light-emitting circuit of the laser device based on a laser emission trigger signal of a first control terminal, to cause the laser device to emit light. The switch unit 12 is adapted to charge the energy storage unit 1B in response to a switch signal of a second control terminal K. A first terminal of the energy storage unit 1B is coupled to the laser device 1A and the switch unit 12, and a second terminal of the energy storage unit is grounded GND, the energy storage unit forms a voltage supply path with a supplied voltage HVDD and the switch unit 12 to perform charging based on the switch signal of the second control terminal K, and to perform discharging based on the laser emission trigger signal of the first control terminal Tr, and forms the light-emitting circuit of the laser device with the drive unit 11 and the ground. The detection unit 13 is adapted to detect an output signal of the first terminal of the energy storage unit, compare the signal with a preset threshold Th, and generate a corresponding state feedback signal S based on a comparison result.

In a specific implementation, the detection unit 13 may be specifically a voltage detection unit or a current detection unit. If the detection unit 13 is the voltage detection unit, the detection unit is adapted to detect a voltage signal outputted at the first terminal of the energy storage unit 1B, compare the signal with a preset threshold voltage Vth, and generate a corresponding state feedback signal S based on a comparison result. If the detection unit 13 is the current detection unit, the detection unit is adapted to detect a current signal outputted at the first terminal of the energy storage unit 1B, compare the signal with a preset threshold current Ith, and generate a corresponding state feedback signal S based on a comparison result. Certainly, the detection unit 13 can further detect other parameters, such as a rate of change of a current or a rate of change of a voltage, as long as the parameter can reflect a luminous intensity of the laser device.

In a specific implementation, the used laser device may be an anode-driven laser device. Correspondingly, a used laser device array may be a common anode-driven laser array. Alternatively, the used laser device may be a cathode-driven laser device. Correspondingly, a used laser device array may be a common cathode-driven laser array. FIG. 1 is a schematic structural diagram of a laser emission drive circuit applied to the cathode-driven laser device according to an embodiment of the description. An operating principle of driving the laser device to operate by using the laser emission drive circuit in this embodiment of the description is described below by using specific applications of the laser device as an example.

When the second control terminal K receives the switch signal, the second control terminal supplies a voltage to the laser device 1A and the energy storage unit 1B through a voltage supply terminal HVDD, to charge the energy storage unit 1B. When the second control terminal K receives a switch-off signal, the second control terminal disconnects the voltage supply terminal HVDD from the laser device 1A and the energy storage unit 1B. When the drive unit 11 receives a laser emission trigger signal through the first control terminal Tr, the energy storage unit 1B, the laser device 1A, the drive unit 11, and the ground form a light-emitting circuit of the laser device 1A. The energy storage unit 1B performs discharging to cause the laser device 1A to emit light, and a voltage HVDD1 at the first terminal of the energy storage unit 1B drops. The detection unit 13 may monitor and determine a change of the voltage HVDD1 at the first terminal of the energy storage unit 1B, so as to deduce a light emission status of the laser device 1A.

Referring to a schematic diagram of a voltage waveform of the first terminal of the energy storage unit shown in FIG. 12, two possible voltage waveforms HVDD1-1 and HVDD1-2 of the first terminal of the energy storage unit detected by the detection unit 13 are shown.

For the voltage waveform HVDD1-2, in a time period t1-t2, the voltage at the first terminal of the energy storage unit drops, which corresponds to the discharging process of the energy storage unit; and in a time period t2-t4, the voltage at the first terminal of the energy storage unit rises, which corresponds to the charging process of the energy storage unit. For the voltage waveform HVDD1-1, in a time period t1-t3, the voltage drops at the first terminal of the energy storage unit, which corresponds to the discharging process of the energy storage unit; and the voltage at the first terminal of the energy storage unit rises in a time period t3-t4, corresponding to the charging process of the energy storage unit.

After the charging process, the energy storage unit can proceed to the discharging process of a next cycle according to a light-emitting timing sequence of the laser device.

The laser emission drive circuit of the embodiment of the description is used. The output signal of the first terminal of the energy storage unit 1B is detected by the detection unit, and compared with the preset threshold value, the corresponding state feedback signal is generated based on the comparison result, which can realize the monitoring of the operating state of the laser device and discover an anomaly in time.

Still referring to FIG. 12, for example, the preset voltage threshold may include at least one of a first voltage threshold VH and a second voltage threshold VL, the detection unit may determine the operating state of the laser device according to a relationship between the voltage signal HVDD1-1 or HVDD1-2 detected at the first terminal of the energy storage unit and the first voltage threshold VH, may also determine the operating state of the laser device according to a relationship between the detected voltage signal HVDD1-1 or HVDD1-2 at the first terminal of the detected energy storage unit and the second voltage threshold VL; or, the detection unit may determine the operating state of the laser device according to the detected voltage signal HVDD1-1 or HVDD1-2 at the first terminal of the energy storage unit in relation to the first voltage threshold VH and the second voltage threshold VL.

In a specific implementation, a specific threshold type, size, quantity, and the like can be set according to a specific monitoring requirement.

Moreover, the switch unit controls on/off between the voltage supply terminal and the laser device, which can prevent the voltage supply terminal from continuously supplying voltage to the laser device, thereby preventing a case that the related circuits of the laser device are instantly broken down and damaged when being short-circuited.

In some embodiments of the description, the voltage provided at the voltage supply terminal may be a higher voltage, for example specifically a high voltage at 12 V, 24 V, 36 V, or more. As shown in the foregoing embodiments and the accompanying drawings, the voltage at the voltage supply terminal may be expressed as HVDD; and correspondingly, the voltage at the first terminal of the energy storage unit may also be a high voltage, as shown in the foregoing embodiments and the accompanying drawings, which is expressed as HVDD1. If the voltage supplied by the voltage supply terminal is less than the higher voltage, the voltage at the voltage supply terminal may be expressed as VDD. Correspondingly, the voltage at the first terminal of the energy storage unit may be expressed as VDD1.

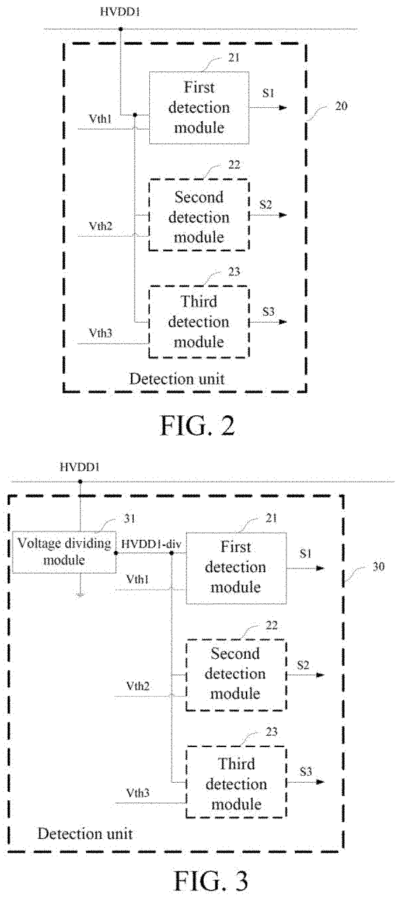

In a specific implementation, the detection unit 13 may include at least one detection module, referring to any one or more detection modules, such as a first detection module 21, a second detection module 22, and a third detection module 23 shown in FIG. 2.

The detection module includes a first input terminal, a second input terminal, and a state feedback signal output terminal, where the first input terminal is adapted to be coupled to a first terminal of the energy storage unit, the second input terminal is adapted for the input of a threshold value corresponding to the detection module, and the state feedback signal output terminal is adapted for the output of the corresponding state feedback signal based on a magnitude relationship between an output signal detected at the first input terminal and a threshold value inputted at the second input terminal.

The laser device certainly consumes electrical energy to emit light. The voltage at the first terminal of the energy storage unit can drive the laser device to emit light and affect the light-emitting intensity of the laser device. The voltage drop amplitude of the first terminal of the energy storage unit can reflect the light-emitting intensity and energy consumption amplitude of the laser device. Therefore, in a specific implementation, by comparing the voltage at the first terminal of the energy storage unit with the voltage threshold corresponding to the corresponding detection module, the electrical energy consumption of the laser device can be determined as well as the electrical energy consumption amplitude, and a light-emitting function of the laser device can be monitored.

A power density of laser emitted from the laser device, even in a small emittance, is quite high and can have an influence on the health of an organism. Therefore, the United States, Japan, the European Union, and other countries and regions formulate corresponding laser safety standards. Among the damage caused by the laser, the damage to eyes is the most serious. A wavelength of the laser varies, a degree of effect on the eyes will be different and a consequence will be different.

For example, for a laser wavelength in the visible light or near infrared light, an absorption rate of a refractive medium of the eyes is low, a transmission rate is high, and the refractive medium has a strong light-concentrating ability. When high intensity visible light or near infrared light enters the eyes, the light can be focused on a retina with the help of the refractive medium in the eyes. In this case, the laser energy density and power density on the retina are instantaneously increased to thousands or even tens of thousands of times. A large amount of light energy is focused on the retina, resulting in a rapid rise in a temperature of a photoreceptor cell layer on the retina, so that the photoreceptor cell coagulates, degenerates and becomes necrotic, and loses photosensitivity. The coagulation and degeneration of proteins caused by overheating when the laser is focused on the photoreceptor cell is irreversible damage. Once the damage occurs, a permanent blindness of the eyes is caused. Far infrared laser damage to the eye is mainly to a cornea. Since the laser having such kind of wavelength is almost all absorbed by the cornea, the cornea suffers the most damage. In contrast, a UV laser damage to the eye mainly affects the cornea and lens.

However, devices that use lasers such as lidar, as mentioned above, are used in a plurality of applications. In order to improve a health and safety degree of an operation of the lidar, a corresponding safety monitoring solution and eyes safety protection solution are required.

As shown in FIG. 2, in some embodiments of the description, the voltage detection module 20 may include a first detection module 21, where a first state feedback signal is outputted by comparing a voltage signal detected at the first input terminal with a first threshold voltage inputted at the second input terminal and when a minimum voltage detected at the first input terminal is less than the first threshold voltage, and the first threshold voltage is related to a human eye safety protection threshold.

In other embodiments of the description, the corresponding first threshold voltage may vary based on differences in characteristics of the protected organism, where the first threshold voltage is related to the corresponding safety protection threshold of the organism. The embodiment of the description does not limit a specific value of the security protection threshold for the organism. For example, when the organism is a human, a threshold voltage th1 may be used; and when the organism is a cat, a threshold voltage th2 may be used.

Specifically, referring to FIG. 2, the first detection module 21 compares a voltage signal HVDD1 at the first terminal of the energy storage unit 1B with a first threshold voltage Vth1, and outputs a first state feedback signal S1 when a minimum value of the voltage HVDD1 detected at the first terminal of the energy storage unit is less than the first threshold voltage Vth1. The first threshold voltage Vth1 is related to a human eye safety protection threshold.

The first threshold voltage Vth1 may be a minimum voltage value at which the electric energy consumed when the light emitted by the laser device affects the health and safety of the eyes. If the voltage HVDD1 at the first terminal of the energy storage unit drops below the first threshold voltage Vth1, it indicates that the voltage of the laser device drops excessively. If the energy consumption of the laser device is excessively large, there is a possibility of causing a certain threat to the eye health and safety of the organisms such as the human eyes. However, the voltage signal at the first terminal of the energy storage unit is compared with the first threshold voltage Vth1 through the first detection module, the voltage can be identified at a first time, and a first state feedback signal is outputted when the minimum value of the voltage at the first terminal of the energy storage unit is detected to be less than the first threshold voltage Vth1. In this way, the corresponding eye safety protection mechanism can be triggered. In a specific implementation, the first threshold voltage Vth1 may be set with factors such as a laser wavelength, a power density, and a pulse width emitted by the laser device.

For example, in order to protect the safety of human eyes, the luminous energy must not exceed several thousand nj in 5 us (depending on the situation of the system, the threshold of each system is different), and the corresponding first threshold voltage is 0.5 V. If the minimum voltage HVDD1 corresponding to this luminescence is 0.1 V, it means that this luminescence is not safe for human eyes.

In a specific implementation, the voltage at the first terminal of the energy storage unit requires to be controlled within a certain drop range when the laser device emits light, in order to ensure the safe and normal operation of the laser device. In order to detect whether the laser device operates normally, the second detection module may be further arranged on the basis of the first detection module arranged in the detection unit. Still referring to FIG. 2, the detection unit 20 may further include: a second detection module 22, where the second detection module 22 compares a voltage signal HVDD1 at the first terminal of the energy storage unit detected at the first input terminal with the second threshold voltage Vth2 inputted at the second input terminal, and outputs a second state feedback signal S2 when a minimum voltage detected at the first input terminal is less than the second threshold voltage Vth2, the second threshold voltage is related to a minimum value of energy required by the laser device for a normal operation, and the second threshold voltage Vth2 is greater than the first threshold voltage Vth1.

A detection unit including the first detection module 21 and the second detection module 22 is used. If the second detection module 22 is detected to output the second state feedback signal S2, and the first detection module 21 is not detected to output the first state feedback signal S1, it indicates that the laser device operates safely and normally.

However, in some cases, if the luminous energy consumption of the laser device cannot reach a preset standard, for example, an open-circuit fault occurs in the laser device, or a fault occurs in the drive unit that drives the laser device, the laser device cannot emit light. Based on the above, in some embodiments of the description, it may be determined that the laser device is not emitting light and that the lidar may have a blind line fault by arranging the first detection module and the second detection module, and if the first state feedback signal and the second state feedback signal are not received within a preset duration after outputting a laser emission trigger signal that drives the laser device to operate, which can be processed according to a preset processing strategy. The so-called “blind line” refers to the line corresponding to the laser device or the channel of the laser device does not emit light.

In a specific implementation, more detection modules can be arranged in order to realize a more accurate detection of the luminescence performance of the laser device. Still referring to FIG. 2, for example, the detection unit 20 may further include a third detection module 23. The third detection module 23 compares a voltage signal detected at the first input terminal with a third threshold voltage inputted at the second input terminal, and outputs a third state feedback signal when a minimum voltage detected at the first input terminal is less than the third threshold voltage. The third threshold voltage is between the first threshold voltage and the second threshold voltage, and is related to a preset luminous intensity of the laser device for that time.

As shown in FIG. 2, the third detection module may compare a voltage signal HVDD1 at the first terminal of the energy storage unit detected at the first input terminal with a third threshold voltage Vth3, and output a third state feedback signal S3 when a minimum value of the voltage HVDD1 detected at the first terminal of the energy storage unit is less than the third threshold voltage Vth3.

In a specific implementation, the detection module in the above embodiment can be specifically realized by a comparator.

In the above embodiments, the voltage at the first terminal of the energy storage unit is directly compared with the preset threshold voltage to determine a fluctuation when the laser device emits the laser. In a specific circuit implementation process, a large high-voltage device is required to be used for driving considering that the supply voltage of the laser device is large. If the comparator is used in the detection module, considering that the comparator is generally a low-voltage device (usually 5 V), the device cannot withstand the voltage HVDD1 at the first terminal of the energy storage unit (for example, 40 V).

Based on the above, in a specific implementation, a voltage dividing module may be arranged instead of directly comparing the voltage at the first terminal of the energy storage unit with the voltage of the preset threshold value. The voltage detected at the voltage dividing module can also reflect the voltage fluctuation at the first terminal of the energy storage unit.

Referring to a schematic structural diagram representing an example detection unit shown in FIG. 3, unlike FIG. 2, the detection unit 30 may further include a voltage dividing module 31, in addition to the detection module (such as at least one of the first detection module 21, the second detection module 22, or the third detection module 23). The voltage dividing module 31 may be connected between the first terminal HVDD1 of the energy storage unit and the ground GND and connected to the first input terminal of at least one detection module (such as the first detection module 21, the second detection module 22, and the third detection module 23) through a voltage dividing terminal HVDD1-div. Therefore, each detection module can compare the voltage dividing terminal HVDD1-div with the respective threshold voltage, and output the corresponding state feedback signal according to the comparison result. After the voltage dividing module 31 is arranged, the threshold voltage Vth corresponding to each detection module is lower than that when the voltage dividing module is not arranged. A specific value can be determined according to a proportional relationship between the voltage HVDD1-div at the voltage dividing terminal and the voltage HVDD1 at the first terminal of the energy storage unit.

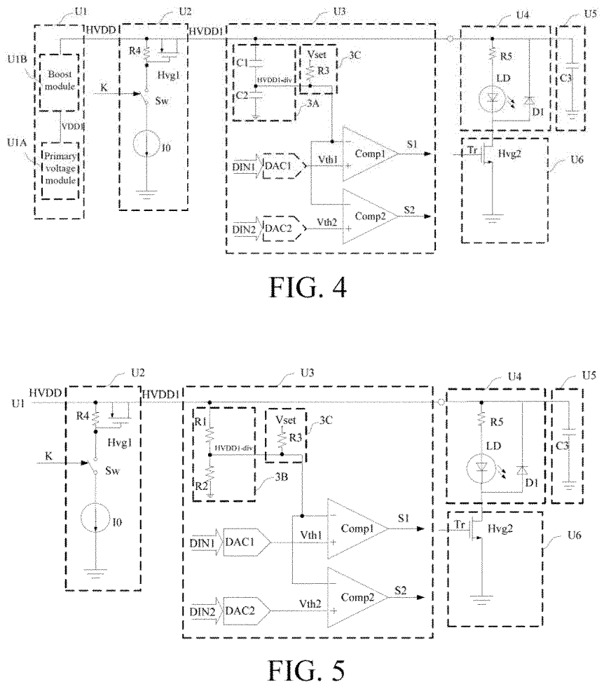

In order to enable a person skilled in the art to better understand and implement the embodiments of the description, specific examples of the implementation of the two voltage dividing modules are given below. First, referring to schematic structural diagrams representing an example laser emission drive circuit shown in FIG. 4 and FIG. 5, a laser emission drive circuit is adapted to be coupled to a laser device U4 and an energy storage unit U5. The laser emission drive circuit may specifically include a switch unit U2, a detection unit U3, and a drive unit U6.

In some embodiments of the description, as shown in FIG. 3 and FIG. 4, the detection unit U3 may include a comparator Comp1 and a comparator Comp2.

Moreover, the voltage dividing module 3A shown in FIG. 4 includes a first capacitor C1 and a second capacitor C2 connected in series between a first terminal HVDD1 of the energy storage unit U5 and the ground GND, where the voltage dividing terminal is arranged between the first capacitor C1 and the second capacitor C2. Here, the voltage HVDD1-div at the voltage dividing terminal and the voltage at the first terminal HVDD1 of the energy storage unit satisfy the following proportional relationship: HVDD1/HVDD1-div=C1+C2/C1.

For another example, a voltage dividing module 3B shown in FIG. 5 includes a first resistor R1 and a second resistor R2 connected in series between the first terminal HVDD1 of the energy storage unit U5 and the ground GND. The voltage dividing terminal is arranged between the first resistor R1 and the second resistor R2. The voltage HVDD1-divat the voltage dividing terminal and the voltage at the first terminal HVDD1 of the energy storage unit satisfy the following proportional relationship: HVDD1/HVDD1-div=R1+R2/R1.

Since a resistor allows a direct current signal to pass through while a capacitor does not allow the direct current signal to pass through, the solution of the voltage dividing module 3A can reduce a direct current loss and has little impact on normal operation of the laser device compared with the solution of the voltage dividing module 3B.

During specific implementation, the voltage at the voltage dividing terminal may be compared with a preset threshold voltage of a corresponding detection module for determination. As shown in FIG. 4 and FIG. 5, the comparator Comp1 compares the voltage HVDD1-div at the voltage dividing terminal with the first threshold voltage Vth1 and outputs a first state feedback signal 51 when the voltage HVDD1-div at the voltage dividing terminal is less than the first threshold voltage Vth1; and the comparator Comp2 compares the voltage HVDD1-div at the voltage dividing terminal with the second threshold voltage Vth2 and outputs a second state feedback signal S2 when the voltage HVDD1-div at the voltage dividing terminal is less than the second threshold voltage Vth2.

It may be learned from above that since the voltage dividing module is coupled between the first terminal of the energy storage unit and the ground, and the voltage dividing terminal of the voltage dividing module is coupled to the first input terminal of the at least one detection module, the voltage at the voltage dividing terminal changes synchronously and proportionally with the change of voltage at the first terminal of the energy storage unit. In this way, the detection module does not need to directly detect the voltage at the first terminal of the energy storage unit. Therefore, the detection module may be implemented by using a low-voltage device (such as a comparator) with a low voltage (such as, 1.8 V or 5 V).

During specific implementation, in order to regulate the voltage at the voltage dividing terminal, a voltage regulating module may be further arranged in the detection unit, which is adapted to initialize the voltage at the voltage dividing terminal. As a specific example, as shown in FIG. 4 and FIG. 5, the voltage regulating module 3C may include a third resistor R3 coupled between the voltage dividing terminal and a preset power supply Vset. The third resistor R3, which is configured as a pull-up resistor, can regulate the voltage HVDD1-div at the voltage dividing terminal by pulling up a voltage of the preset regulating voltage supply Vset. Therefore, a starting point of fluctuation of the voltage HVDD1-div at the voltage dividing terminal detected each time remains the same, which improves the accuracy of voltage detection.

In a specific implementation, a digital signal processor such as a processor, a controller, a Field-Programmable Gate Array (FPGA), or a single-chip microcomputer can be used as the control unit to control the laser emission drive circuit in the embodiments of the description. Therefore, the laser emission drive circuit may further include a digital to analog converter (DAC) module. The DAC module may be coupled between the control unit and the second input terminal of the corresponding detection module and is adapted to convert a received threshold voltage digital signal into a corresponding threshold voltage analog signal. As shown in FIG. 4 and FIG. 5, an input threshold voltage digital signal DIN1 can be converted into the first threshold voltage Vth1 by DAC1, and an input threshold voltage analog signal DIN2 can be converted into the second threshold voltage Vth2 by DAC2.

Based on different modes of operation, the emitted power may vary and the supply voltage of the laser device may also vary. In order to cause the generated state feedback signal more truly reflect an actual operating situation of the laser device, in the specific implementation, the threshold voltage corresponding to the detection module can be set to change synchronously with the voltage at the voltage supply terminal. As an optional example, the voltage HVDD at the voltage supply terminal and the threshold voltage Vth corresponding to the detection module can be synchronously controlled by the control unit.

In some embodiments of the description, referring to FIG. 4 and FIG. 5, the energy storage unit U5 may include a third capacitor C3.

In a specific implementation, referring to FIG. 4, a capacitance value of the third capacitor C3 can be set to be much greater than a capacitance value of the first capacitor C1 and a capacitance value of the second capacitor C2, so that an influence of the detection unit U3 on the luminescence of the laser device U4 is as small as possible. As a specific example, the capacitance value of the third capacitor C3 may be more than a thousand times greater than the capacitance value of the first capacitor C1 and the capacitance value of the second capacitor C2. That is, a ratio of a capacitance value of the third capacitor C3 to a capacitance value of either the first capacitor C1 or the second capacitor C2 is greater than 1000.

In order to enable a person skilled in the art to better understand and implement the embodiments of the description, a specific example solution of a switch unit is shown below. Referring to FIG. 4 and FIG. 5, the switch unit U2 may include a fourth resistor R4, a DC current source 10, a first transistor Hvg1, and a control switch Sw.

A first terminal of the fourth resistor R4 is coupled to the voltage supply terminal HVDD. A first terminal of the DC current source 10 is coupled to the ground GND and a second end of the DC current source is coupled to a second terminal of the fourth resistor R4. A first pole of the first transistor is coupled to the voltage supply terminal HVDD, and a second pole of the first transistor is coupled to the first terminal HVDD1 of the energy storage unit and is coupled to the second terminal of the fourth resistor R4 through a control pole. The control switch Sw is coupled between the control pole of the first transistor and the ground, and controls the charge or discharge of the energy storage unit in response to an on-off control signal of the second control terminal.

As shown in FIG. 4 and FIG. 5, as an example, the first transistor may specifically use a high-voltage switching tube Hvg1. The current source 10 is connected to a gate of the high-voltage switching tube Hvg1 through the switch Sw, and a voltage drop is formed by engaging with the resistor R4. In this way, opening and closing of the high-voltage switching tube Hvg1 can be controlled. When the high-voltage switching tube Hvg1 is closed, the energy storage unit U5, the switch unit U2, and the voltage supply terminal HVDD form a voltage supply path, and the voltage supply terminal HVDD supplies the high voltage to the detection unit U3 and the third capacitor C3 to charge the third capacitor C3; and when the high-voltage switching tube Hvg1 is disconnected, if the laser emission trigger signal of the first control terminal controls the drive unit U6 on, the corresponding third capacitor C3 discharges, and the drive unit U6 and the ground form the light-emitting circuit of the laser device U4, so that the laser device U4 emits light. The voltage HVDD1 at the first terminal of the energy storage unit U5 drops, and the detection unit U3 starts operating to determine the voltage change of the first terminal HVDD1 of the energy storage unit U5 and to further infer the light emission of the laser device U4. The switch unit U2 operates in collaboration with the detection unit U3 so that the voltage fluctuation at the first terminal HVDD1 of the energy storage unit U5 can be easily captured.

In a specific implementation, as shown in FIG. 4, the laser emission drive circuit may further include a power supply unit U1. The laser device U4 is powered by the power supply unit U1. In some embodiments of the description, the power supply unit includes a primary voltage module U1A and a boost module U1B. A voltage VDD1 with a smaller voltage value may be generated by the primary voltage module U1A. Through the boost module U1B, the voltage VDD1 can be boosted to the HVDD, and output to the voltage supply terminal HVDD to supply power to the laser device U4.

It should be noted that a specific circuit structure of the power supply unit is not limited in the embodiment of the description, let alone specific circuit structures of the primary voltage module and the boost module, as long as the power supply voltage required for a normal operation of the laser device can be provided.

In a specific implementation, the laser emission drive circuit described in the foregoing embodiments can be arranged on a printed circuit board to engage the laser device and drive the laser device to operate.

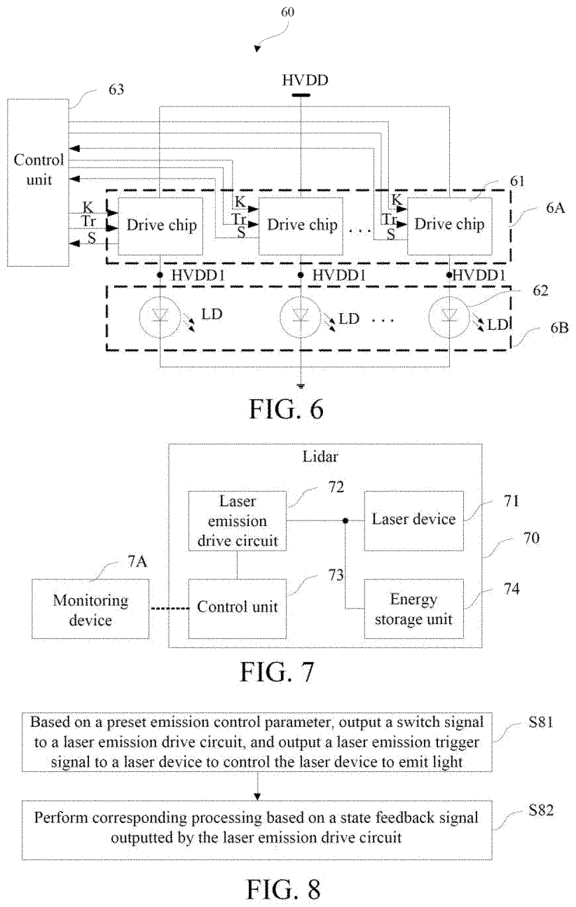

In other embodiments of the description, an integrated circuit packaging manufacturing process is used for obtaining a drive chip containing the laser emission drive circuit described in the foregoing embodiments. As shown in FIG. 6, FIG. 6 is a schematic structural diagram of an example lidar emission system according to an embodiment of the description. The laser emission system 60 may include a drive chip 61 and a laser device 62 in the embodiment of the description. One or more drive chips 61 may be arranged. Correspondingly, one or more laser devices 62 may be arranged. Each drive chip 61 is configured to drive the corresponding laser device 62. A specific structure and operating principle of the laser emission drive circuit included in the drive chip may be referred to the description of the foregoing embodiments and details are not described again herein.

An input terminal of each drive chip 61 is connected to the voltage supply terminal HVDD, and an output terminal of each drive chip is connected to the first terminal HVDD1 of the corresponding energy storage unit (not shown in FIG. 6) (as shown in FIG. 6, an anode side of a laser diode LD). The voltage supply terminal HVDD supplies the voltage HVDD to the drive chip 61. Under the control of the laser emission trigger signal Tr and the switch signal K, the drive chip 61 outputs the drive voltage HVDD1 and drives the laser device 62 to emit light.

As shown in FIG. 6, the laser emission system 60 may further include a control unit 63. The control unit is connected to the drive chip 61. The laser emission trigger signal Tr and the switch signal K can be generated for each drive chip according to a ranging requirement, so that each laser device 62 can be successively strobed to emit light, and some lasers may also be selected to emit light at the same time. A luminescence mode can be determined according to a detection requirement, which is not limited here. That is to say, the control unit 63 can determine the laser device 62 that requires to be driven, and provide the corresponding laser emission trigger signal Tr and switch signal K for the drive chip of the laser device 62. Each drive chip 61 can output a corresponding state feedback signal S to the control unit 63 by detecting the voltage HVDD1 at the first terminal of the energy storage unit, so as to feedback an operating state of the driven laser device 62.

It can be understood by a person skilled in the art that although the input to the control terminal of each drive chip 61 is shown as Tr and K in FIG. 6, the laser emission trigger signal Tr and the switch signal K of each drive chip 61 can be different depending on a different ranging requirement.

Here, the laser emission trigger signal Tr is a trigger signal of the drive chip 61, which is emitted at each ranging by a radar (for example, scanning every few microseconds). Each laser emission trigger signal Tr may include one or a plurality of (such as, 2 to 4) narrow pulses. The pulse width of each narrow pulse is a few tens of nanoseconds, proportional to the luminous power of the laser device 62. The switch signal K is a control signal of the drive chip 61, and the closing time may be changed with a change of the ranging requirement. For example, a value of an environmental obstacle may be lowered when the obstacle has a high reflective surface, while a value of an environmental obstacle may be increased when the obstacle has a low reflective surface.

Moreover, although the drive chip 61 and the laser device 62 are shown as one-to-one correspondence in FIG. 6, a person skilled in the art can understand that one drive chip 61 can drive a plurality of laser devices 62 depending on an actual situation.

The laser device 62 may be, for example, an edge emitting laser (EEL) or a vertical-cavity surface emitting laser (VCSEL), and the like.

In a specific implementation, still referring to FIG. 6, one or more drive chips 61 may be packaged in a packaging structure 6A, and one or more laser devices 62 may be packaged in an other packaging structure 6B.

It can be understood by a person skilled in the art that other parts of the lidar, such as a receiver, are omitted here for a sake of brevity. Moreover, the system structure of the laser emission system is also applicable to the laser emission drive circuit.

An embodiment of the description further provides a lidar capable of employing the laser emission drive circuit. The lidar may have a plurality of light-emitting channels, each light-emitting channel may correspond to a laser device, and each light-emitting channel emits a wire harness. The lasers are staggered vertically relative to each other along a direction of a rotation axis of the lidar (that is, each laser device has a different vertical angle), either specifically in a single column or in staggered columns. For each light-emitting channel, there is a different detection requirement due to the corresponding different vertical angle, which in turn corresponds to a different light-emitting intensity. For example, it may be desirable to detect farther for a channel in a middle of a harness. Correspondingly, it is desirable that the light intensity is stronger, while an opposite is true for a channel on either side.

As shown in FIG. 7, in an embodiment of the description, the lidar 70 may include a laser device 71, a laser emission drive circuit 72, a control unit 73, and an energy storage unit 74.

The laser device 71 is adapted to emit a laser in response to a laser emission trigger signal. A specific implementation of the laser emission drive circuit 72 may be referred to the foregoing embodiments and details are not described herein again. The control unit 73 is adapted to output a switch signal k to control a switch unit in the laser emission drive circuit to strobe a voltage supply path to charge the energy storage unit; output a laser emission trigger signal Tr to control the drive unit to strobe a light-emitting circuit of the laser device; and receive a state feedback signal S generated by the laser emission drive circuit S, and perform corresponding processing based on the state feedback signal S. The energy storage unit 74 is adapted to be coupled to the laser emission drive circuit 72 and the laser device 71 and to perform discharging based on the laser emission trigger signal outputted by the control unit 73 and to perform charging based on the switch signal outputted by the control unit 73.

Only the device corresponding to one light-emitting channel is shown in FIG. 7, and each light-emitting channel can have a corresponding laser device 71, a laser emission drive circuit 72, and an energy storage unit 74.

The specific implementation of the energy storage unit 74 and the specific electrical connection relationship with the laser emission drive circuit 72 and the laser device 71 can be found in a detailed description of the foregoing embodiment of the laser emission drive circuit.

In a specific implementation, the control unit 73 may perform the corresponding processing based on whether the state feedback signal S is received and a type of the state feedback signal S received.

In order to enable a person skilled in the art to better understand and implement an exception handling operation for the control unit 73, the following is illustrated by some specific examples.

For example, the control unit 73 receives the first state feedback signal S1. Combined with FIG. 4 and FIG. 5, in an embodiment of the description, the control unit 73 generates a laser device turn-off signal in response to the first state feedback signal S1 to control the laser device 71 to stop operating. In another embodiment of the description, the control unit 73 is adapted to control the first terminal of the energy storage unit 74 to ground in response to the first state feedback signal S1, set a corresponding emission channel of the laser device as a prohibited light-emitting channel, and output human eye safety alarm information.

More specifically, referring to FIG. 4 and FIG. 5, when the control unit 73 receives the first state feedback signal, the control unit U6 can perform at least one of the following feasible safety protection operations to control the laser device to stop emitting. 1) An output of the laser emission trigger signal Tr to the drive unit U6 can be stopped; 2) an anode voltage of the laser device LD can be pulled down to stop the laser device LD from operating; and 3) a path from the voltage supply terminal HVDD to the first terminal HVDD1 of the energy storage unit is switched to a high resistance state for current limiting.

The control unit U6 specifically may be a controller, which may be an upper bin board controller or a lower bin board controller.

In a specific implementation, the human eye safety alarm information can be outputted to a monitoring device 7A coupled with the lidar. The monitoring device 7A may specifically be a device that installs the lidar (such as a vehicle or a sweeping robot, and the like) or a terminal device such as a mobile phone terminal, a computer terminal, or a cloud monitoring device. The monitoring device 7A can transmit an alarm signal to a user through at least one of the modes, such as a display, a voice or a warning light, or an alarm message (such as an E-mail and a short message).

During specific implementation, the user may set up a dedicated monitoring and management account, and pre-establish a correspondence between the lidar and the monitoring and management account. During the operation of the lidar, the human eye safety alarm information may be transmitted to the monitoring and management account. As a specific example, the user may log in to the monitoring and management account through the terminal device to obtain state feedback information about the lidar, including the human eye safety alarm information, and then take a corresponding fault maintenance measure for the lidar.

In another embodiment of the description, the state feedback signal S includes a first state feedback signal S1 and a second state feedback signal S2. The control unit 73 is adapted to perform processing according to a preset abnormality processing strategy when the control unit does not receive the first state feedback signal S1 and the second state feedback signal S2 within a preset duration since the laser emission trigger signal is outputted.

As a specific example, the control unit 73 performs accumulative counting when the control unit does not receive the first state feedback signal S1 and the second state feedback signal S2 within the preset duration since the laser emission trigger signal is outputted, and outputs a blind line alarm signal when a counted value reaches a preset counting threshold. A failure of receiving the first feedback signal S1 and the second feedback signal S2 at a time may result from signal interference. Therefore, a counter may be arranged to perform accumulative counting. When neither the first feedback signal S1 nor the second feedback signal S2 is received when the counted value reaches the preset counting threshold, a blind line alarm signal is outputted to confirm a fault of the emission channel where the laser device 71 is located. Specifically, the fault may be a fault of a laser device or a fault of a laser emission drive circuit (such as the drive unit). The user may perform troubleshooting after receiving the blind line alarm signal.

In another embodiment of the description, the state feedback signal S includes a third state feedback signal S3, and the control unit 73 outputs a corresponding excessive light intensity alarm signal when receiving the third state feedback signal.

In order to enable a person skilled in the art to better understand and implement the embodiments of the description, a specific structure of an example circuit of a laser device is described below. Referring to FIG. 4 and FIG. 5, a laser device U4 includes: a laser diode LD, a fifth resistor R5, and a freewheeling diode D1.

A cathode of the laser diode LD is coupled to the drive unit U6. The fifth resistor R5 is coupled between an anode of the laser diode LD and a high voltage terminal HVDD1 of the laser device U4. The freewheeling diode D1 is reversely connected in parallel to the cathode of the laser diode LD and the first terminal HVDD1 of the energy storage unit.

A current mutation of the laser diode LD can be prevented by the freewheeling diode D1 to avoid a breakdown of the laser diode LD.

In a specific implementation, the control unit can output a preset pulse signal as the laser emission trigger signal Tr. As mentioned before, a single pulse signal or a plurality of continuous pulse signals can be outputted, and the pulse width and the amplitude of the pulse signal can be preset as required, such as according to a measurement distance.

Referring to the flowchart of an example method for laser emission control shown in FIG. 8, it may be applicable to the lidar described in any of the foregoing embodiments, and may specifically include the following steps.

S81: Based on a preset emission control parameter, output a switch signal to the laser emission drive circuit, and output a laser emission trigger signal to the laser device to control the laser device to emit light.

The preset emission control parameter here may include at least one of an emission time sequence, an emission power, a pulse width, and a quantity of continuously transmitted pulse signals of each laser device.

S82: Perform corresponding processing based on the state feedback signal outputted by the laser emission drive circuit.

The state feedback signal outputted by the laser emission drive circuit and the corresponding processing can refer to the foregoing embodiments.

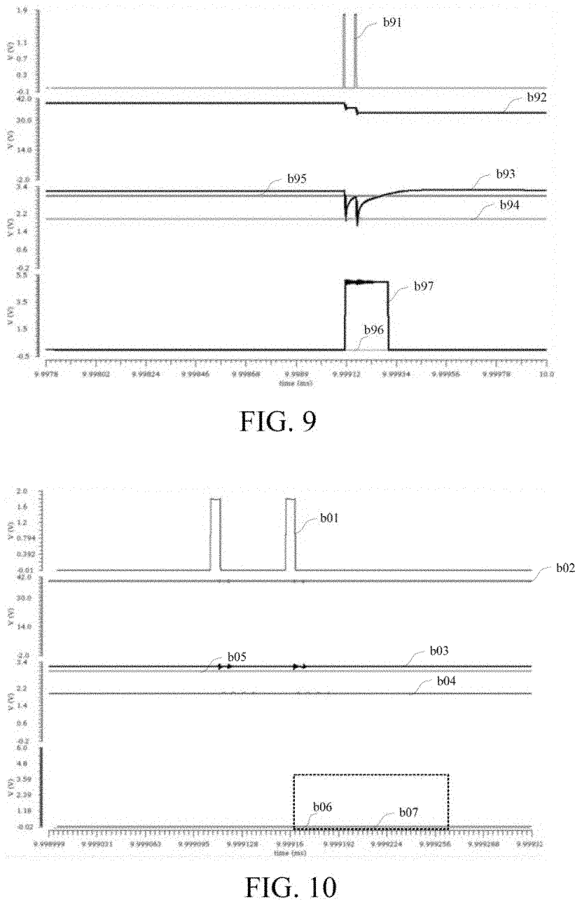

In order to enable a person skilled in the art to better understand and implement the embodiments of the description, referring to FIG. 9 to FIG. 11, the operating principle is illustrated by the specific waveform diagram corresponding to the laser emission drive circuit shown in FIG. 4.

Firstly, referring to FIG. 9, the control unit outputs a laser emission trigger signal b91. That is, two consecutive pulse signals exist near 9.99 ms. In this case, the laser device emits light correspondingly. The waveform of the voltage signal b92 at the first terminal of the energy storage unit fluctuates slightly, and the waveform of the voltage signal b93 at the corresponding voltage dividing terminal HVDD1-esdiv also fluctuates. The voltage signal b93 at the voltage dividing terminal HVDD1-esdiv is compared with a preset first threshold voltage b94 and a preset second threshold voltage b95. When the voltage signal b93 at the HVDD1-esdiv is less than the preset second threshold voltage b95, a second state feedback signal b97 is outputted; and it can be learned from FIG. 9 that the voltage signal b93 at the HVDD1-esdiv is not substantially less than the preset first threshold voltage b94, therefore the first state feedback signal b96 is not outputted.

FIG. 10 depicts a specific waveform diagram corresponding to an example laser emission drive circuit. The control unit outputs a laser emission trigger signal b01. That is to say, the two consecutive pulses around 9.99 ms correspond to the laser device being in a light-emitting state. However, the waveform of the voltage signal b02 at the first terminal of the energy storage unit does not fluctuate, nor does the waveform of the voltage signal b03 at the corresponding voltage dividing terminal HVDD1-esdiv. The voltage signal b03 at the voltage dividing terminal HVDD1-esdiv is compared with the preset first threshold voltage b04 and the preset second threshold voltage b05. When the voltage signal b03 at HVDD1-esdiv is greater than the preset second threshold voltage b05, the second state feedback signal, such as a waveform b07, is not outputted; and when the voltage signal b03 at HVDD1-esdiv is greater than the preset first threshold voltage b04, the first state feedback signal is not outputted, as shown in a waveform b06. It can be learned from FIG. 10 that neither the first state feedback signal b06 nor the second state feedback signal b07 is outputted during a period shown in a dotted box 10A in the figure.

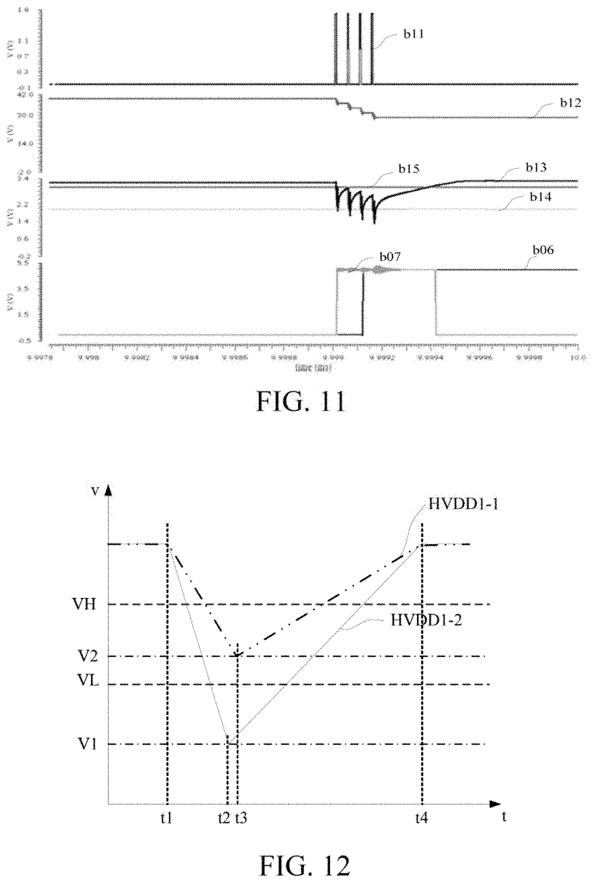

Next, referring to a specific waveform diagram corresponding to an example laser emission drive circuit shown in FIG. 11, the control unit outputs a laser emission trigger signal b11. That is to say, four consecutive pulses around 9.99 ms correspond to the laser device being in the light-emitting state. However, a waveform of a voltage signal b12 at the first terminal HVDD1 of the energy storage unit fluctuates in four steps, and a waveform of a voltage signal b13 at the corresponding voltage dividing terminal HVDD1-esdiv also fluctuates accordingly. The voltage signal b13 at the voltage dividing terminal HVDD1-esdiv is compared with the preset first threshold voltage b14 and the preset second threshold voltage b15. When the voltage signal b13 at the HVDD1-esdiv is less than the preset second threshold voltage b15, the second state feedback signal is outputted, such as a waveform b17. When the voltage signal b13 at the HVDD1-esdiv is less than the preset first threshold voltage b04, the first state feedback signal is outputted, as shown in a waveform b06.

In order to further improve the safety of human eyes, in a specific implementation, once the voltage signal b13 at the HVDD1-esdiv is detected to be less than the preset first threshold voltage b04, the high level is continuously maintained, as shown in the waveform b06 in FIG. 11. Correspondingly, the laser device may take measures such as continuously outputting an alarm signal, continuously maintaining the emission channel in which the laser device is located in a no-emission state, and the like, so as to provide good protection for the eye health and safety.

Although the embodiments of the present disclosure are disclosed as above, the present disclosure is not limited thereto. A person skilled in the art can make various changes and modifications without departing from the spirit and the scope of the present disclosure. Therefore, the protection scope of the present disclosure should be subject to the scope defined by the claims.

What is claimed is:

1. A laser emission drive circuit, configured to be coupled to a laser device and an energy storage unit, wherein the laser emission drive circuit comprises a drive unit, a switch unit, and a detection unit, wherein
the drive unit is configured to strobe a light-emitting circuit of the laser device based on a laser emission trigger signal of a first control terminal, to cause the laser device to emit light;
the switch unit is configured to strobe a voltage supply path in response to a switch signal of a second control terminal, and to charge the energy storage unit;
a first terminal of the energy storage unit is coupled to the laser device and the switch unit, and a second terminal of the energy storage unit is grounded, the energy storage unit forms the voltage supply path with a supplied voltage and the switch unit and forms the light-emitting circuit of the laser with the drive unit and the ground, the energy storage unit being configured to perform charging based on the switch signal of the second control terminal and perform discharging based on the laser emission trigger signal of the first control terminal; and
the detection unit is coupled to the switch unit, the laser device, and the energy storage unit, and is configured to detect a signal of the first terminal of the energy storage unit during discharging and generate a corresponding state feedback signal based on a comparison of the signal with a preset threshold.

2. The laser emission drive circuit according to claim 1, wherein the detection unit comprises at least one detection module; and
the detection module comprises a first input terminal, a second input terminal, and a state feedback signal output terminal, wherein the first input terminal is configured to be coupled to the first terminal of the energy storage unit, the second input terminal is configured for the input of a threshold corresponding to the detection module, and the state feedback signal output terminal is configured for the output of the corresponding state feedback signal based on a magnitude relationship between an output signal of the energy storage unit detected at the first input terminal and the threshold inputted at the second input terminal.

3. The laser emission drive circuit according to claim 2, wherein the detection unit comprises:
a first detection module, configured to compare a voltage signal detected at the first input terminal with a first threshold voltage inputted by the second input terminal, and output a first state feedback signal when a minimum voltage detected at the first input terminal is less than the first threshold voltage, wherein the first threshold voltage is related to a human eye safety protection threshold.

4. The laser emission drive circuit according to claim 3, wherein the detection unit further comprises:
a second detection module, configured to compare the voltage signal detected at the first input terminal with a second threshold voltage inputted by the second input terminal, and output a second state feedback signal when the minimum voltage detected at the first input terminal is less than the second threshold voltage, wherein the second threshold voltage is related to a minimum energy required for normal operation of the laser device, and the second threshold voltage is greater than the first threshold voltage.

5. The laser emission drive circuit according to claim 4, wherein the detection unit further comprises:
a third detection module, configured to compare a voltage signal detected at the first input terminal with a third threshold voltage inputted at the second input terminal, and output a third state feedback signal when the minimum voltage detected at the first input terminal is less than the third threshold voltage, wherein
the third threshold voltage is between the first threshold voltage and the second threshold voltage, and is related to a current preset luminous intensity of the laser device.

6. The laser emission drive circuit according to claim 2, wherein the detection unit further comprises:
a voltage dividing module, coupled between the first terminal of the energy storage unit and the ground and coupled to the first input terminal of the at least one detection module through a voltage dividing terminal; and
a voltage regulating module, configured to initialize the voltage at the voltage dividing terminal.

7. The laser emission drive circuit according to claim 6, wherein the voltage dividing module comprises a first capacitor and a second capacitor coupled between the first terminal of the energy storage unit and the ground, and the voltage dividing terminal is arranged between the first capacitor and the second capacitor.

8. The laser emission drive circuit according to claim 7, wherein the energy storage unit comprises a third capacitor, and a ratio of a capacitance value of the third capacitor to a capacitance value of either the first capacitor or the second capacitor is greater than 1000.

9. The laser emission drive circuit according to claim 6, wherein the voltage dividing module comprises a first resistor and a second resistor coupled between the first terminal of the energy storage unit and the ground, and the voltage dividing terminal is arranged between the first resistor and the second resistor.

10. A lidar, comprising:
a laser device, configured to emit a laser in response to a laser emission trigger signal;
an energy storage unit coupled to the laser device;
a laser emission drive circuit coupled to the laser device and the energy storage unit; and
a control unit, configured to:
output a switch signal to control a switch unit in the laser emission drive circuit to strobe a voltage supply path to charge the energy storage unit;
output a laser emission trigger signal to control a drive unit in the laser emission drive circuit to strobe a light-emitting circuit of the laser device, to cause the laser device to emit light; and
receive a state feedback signal generated by the laser emission drive circuit;
wherein the energy storage unit is configured to perform discharging based on the laser emission trigger signal outputted by the control unit, and to perform charging based on the switch signal outputted by the control unit.

11. The lidar according to claim 10, wherein the control unit is further configured to perform corresponding processing based on a determination that the state feedback signal is received and a type of the state feedback signal.

12. The lidar according to claim 11, wherein the state feedback signal comprises a first state feedback signal, and the control unit is further configured to generate a laser device turn-off signal in response to the first state feedback signal, to control the laser device to stop operating.

13. The lidar according to claim 11, wherein the state feedback signal comprises a first state feedback signal, and the control unit is further configured to:
control a first terminal of the energy storage unit to be grounded;
set an emission channel corresponding to the laser device as a light-emission-prohibited channel; and
output human eye safety alarm information in response to the first state feedback signal.

14. The lidar according to claim 11, wherein the state feedback signal comprises a first state feedback signal and a second state feedback signal, and the control unit is further configured to perform accumulative counting when the control unit receives neither of the first state feedback signal and the second state feedback signal within a preset duration since the laser emission trigger signal is outputted, and to output a blind line alarm signal when a counted value reaches a preset counting threshold.

15. The lidar according to claim 11, wherein the state feedback signal comprises a third state feedback signal, and the control unit is further configured to output a corresponding excessive light intensity alarm signal when receiving the third state feedback signal.

16. The lidar according to claim 10, wherein the laser emission drive circuit comprises a detection unit that is configured to detect a signal of a second terminal of the energy storage unit during discharging and generate a corresponding state feedback signal based on a comparison of the signal with a preset threshold.

17. A method for controlling laser emission of a lidar, comprising:
based on a preset emission control parameter, outputting a switch signal to a laser emission drive circuit of the lidar to strobe a voltage supply path to charge an energy storage unit;
outputting a laser emission trigger signal to the laser emission drive circuit to strobe a light-emitting circuit of a laser device of the lidar to control the laser device to emit light;
receiving a state feedback signal generated by the laser emission drive circuit; and
controlling the lidar based on the state feedback signal outputted by the laser emission drive circuit.

18. The method of claim 17, wherein the preset emission control parameter comprises at least one of an emission time sequence, an emission power, a pulse width, and a quantity of continuously transmitted pulse signals of the laser device.

19. The method of claim 17, wherein the energy storage unit is configured to perform discharging based on the laser emission trigger signal.

20. The method of claim 17, wherein the state feedback signal is generated based at least in part on a comparison of a signal of the energy storage unit with a preset threshold.
